(19) United States
(12) Patent Application Publication
(10) Pub. No.: US 2006/0263176 A1
(43) Pub. Date: Nov. 23, 2006

(54) Storage system for wafers and other objects used in the production of semiconductor products

(76) Inventor: Thomas J. Moran, Radolfzell-Stahringen (DE)

Correspondence Address: HARNESS, DICKEY & PIERCE, P.L.C., P.O. BOX 828, BLOOMFIELD HILLS, MI, 48303, US

(21) Appl. No.: 11/320,443

(22) Filed: Dec. 28, 2005

Related U.S. Application Data
(63) Continuation of application No. PCT/EP04/06657, filed on Jun. 19, 2004.

(30) Foreign Application Priority Data
Jul. 2, 2003 (DE) 103 29 868.1

(51) Int. Cl. H01L 21/677

(52) U.S. Cl. 414/217

(57) ABSTRACT

A storage system for objects such as wafers or reticles has at least one storage module, in which the objects are stored one above the other in packets similar to a column. Located next to the storage module is an inserting and dispensing module which comprises a robot. The robot has an arm which is movable substantially in a horizontal plane and with which predetermined objects can be laterally removed from or inserted into a predetermined packet. The packets are arranged in the storage module on a conveyor that runs substantially in a horizontal plane. The predetermined packet can be brought by the conveyor into a transfer position, at which the predetermined object can be transferred between the arm and the predetermined packet.

### CROSSREFERENCES TO RELATED APPLICATIONS

The present application is a continuation of international patent application PCT/EP2004/006657 filed on Jun. 19, 2004 and published in German language, which international patent application claims priority under the Paris Convention from German patent application DE 103 29 868.1.

### BACKGROUND OF THE INVENTION

The invention relates to a storage system for objects used in the production process of semiconductor products, and more particularly to a storage system for objects such as wafers and reticles.

In the production of integrated circuits and other semiconductor products, it is known to use circular flat semiconductor substrates of 300 mm in diameter, for instance, commonly known as wafers. Reticles are disk type objects that are used in the process of transferring a circuit structure onto such a wafer. Wafers and reticles have been kept clean during the production process. Hence, they are typically buffer-stored between various processing steps.

Known storage system have limited storage capacity in relation to the base area required for or covered by the storage system. Furthermore, they employ robots for handling the wafers and reticles, which robots require complicated moving operations in order to reach any storage location in the system.

### SUMMARY OF THE INVENTION

It is an object of the invention to provide for a storage system for storing objects used in the production of semiconductor products, which storage system provides a high storage capacity in relation to the ground area occupied.

It is another object of the present invention to provide for a storage system which allows simple and quick movements of a handling robot used for transferring objects into and out of the system.

According to one aspect of the invention, there is provided a storage system for storing a plurality of wafers, comprising a storage module comprising at least one conveyor formed as a carousel and adapted to rotate about an axis of rotation, and an inserting and dispensing module comprising a robot having a robot arm movable in a substantially horizontal plane, the inserting and dispensing module being located next to the storage module, wherein the carousel has an inner turntable and an outer turntable capable of rotating independently of each other about the axis of rotation, wherein the wafers are stored in a plurality of packets located on the inner turntable and the outer turntable, with the packets forming columns of wafers with one wafer above the other, wherein the robot is configured to insert a specific wafer into one of the plurality of packets or to remove a specific wafer from one of the plurality of packets, and wherein the conveyor is configured to bring the one of the plurality of packets into a transfer position at which the specific wafer can be transferred between the robot arm and the one packet.

According to another aspect, there is provided a system for storing objects used in the production of semiconductor products, the system comprising at least one conveyor running substantially in a horizontal plane, and a robot having a robot arm movable in the horizontal plane, wherein the conveyor is configured to support a plurality of objects in column like arrangements with one object above the other, wherein the robot is designed to insert a specific object into one of the column like arrangements or to remove the specific object from the one of the column like arrangements, and wherein the conveyor is configured to bring the one of the column like arrangements into a transfer position at which the specific object can be transferred between the robot arm and the packet.

Due to the fact that the robot only has to be moved to a single position, namely the transfer position, the moving operations are simplified. In addition, moving the packets on the conveyor has the advantage that it is no longer necessary to take care for the moving operations of the robot and the packets can therefore be arranged much closer together and not necessarily in such a way that they are individually accessible for the robot arm. In this way, packing density can be increased. While retaining a single robot with its limited area requirement, far more packets can be stored in the same storage system.

In a preferred refinement of the storage system, the conveyor is formed as a carousel.

This measure has the advantage that the required moving operations for the packets can be implemented in a very simple manner.

It is particularly preferred if the carousel has an inner turntable and an outer turntable, which are rotatable independently of each other about a vertical axis.

This measure has the advantage that the packing density of the packets can be further increased, without hindering accessibility or increasing the complexity of the moving operation.

This applies in particular to a refinement of the aforementioned variant in which the inner turntable and the outer turntable each are assigned a transfer position, these transfer positions being arranged substantially on a radial line that runs through the vertical axis, and wherein the outer turntable is capable of moving to its transfer position with an empty location, whenever the inner turntable moves the predetermined packet into the transfer position of the inner turntable for transferring the predetermined wafers.

This measure has the advantage that optimum access is possible to all the packets of the outer turntable and the inner turntable with very simple moving sequences. This applies in particular to the moving of the arm in its horizontal plane, because, when moving it to one or the other transfer position, it only has to be slightly moved in a linear direction along the radial line.

The objects can be transferred either individually or in groups in such storage systems, the latter in particular in some sort of baskets.

In the case of further exemplary embodiments of the invention, it is preferred if two substantially identical storage modules are arranged next to the inserting and dispensing module, the robot being in operative connection with both storage modules.

This measure has the advantage that a further increase in the packing density, and consequently a further reduction in the space requirement, is achieved if the robot is assigned not just one but two storage modules, possibly even three or more storage modules, which are all commonly handled by the one robot. The space requirement that is required for the robot then only has to be used once, and the capacity of the storage system is correspondingly increased.

In embodiments of the invention the robot can be made to move by means of a vertical unit. In this case, it is further preferred if the arm is a bending arm.

These measures have the advantage that all the storage locations can be moved to the transfer positions with very simple moving sequences of the robot. This leads to a reduction in the moving time and consequently to a reduction in the access time within the storage system.

It is further preferred within the scope of the present invention if the inserting and dispensing module has a sensor and positioning unit for sensing and, if applicable, for correcting the rotational position of the objects and/or a reader for reading a marking on the objects.

These measures have the advantage that the path of each individual object can be continuously documented. This relates in particular to standard markings (bar codes), which are arranged on the edge of wafers at a defined spacing from what is called “notch”, i.e. a semicircular indentation at the circumference of the wafer.

Said measures have the advantage that the position of the notch can be detected in a simple way. If it is thereby found that the wafer is not located with its notch at the defined circumferential position, the wafer can first be turned, for example by means of a turntable, until the notch is at the desired position. Then, the marking lying next to the notch can be read out and, consequently, it can be ensured that the inserting or dispensing of the wafer is documented in an appropriate form.

All this preferably takes place according to the invention in the region of inserting and dispensing stations for the wafers, which are likewise provided on the inserting and dispensing module.

In the case of a further group of exemplary embodiments, the storage module has a housing which is closed with the exception of an opening facing the inserting and dispensing module.

This measure has the advantage that the stored objects can be optimally protected against contamination.

For carrying out servicing work and the like, a closable door may also be provided in the housing in accordance with the invention.

In order that the objects can be stored within the storage module free from contamination, laminar flow units and/or electrostatic discharge units are additionally provided on the storage module and/or also on the inserting and dispensing module.

These measures ensure that the objects are only exposed to a clean-room atmosphere, which is moreover free from electrostatic charges.

Further advantages emerge from the following description and the accompanying drawings.

It goes without saying that the features mentioned above and those to be explained below can be used not only in the respectively specified combination but also in other combinations or on their own without departing from the scope of the present invention.

### BRIEF DESCRIPTION OF THE DRAWINGS

An exemplary embodiment of the invention is explained in more detail in the description which follows and is represented in the drawing, in which:

FIG. 1 shows an exemplary embodiment of a storage system according to the invention in a lateral sectional view along the line I-I of FIG. 2;

FIG. 2 shows a plan view of the storage system according to FIG. 1, likewise in section and along a line II-II of FIG. 1.

### DESCRIPTION OF PREFERRED EMBODIMENTS

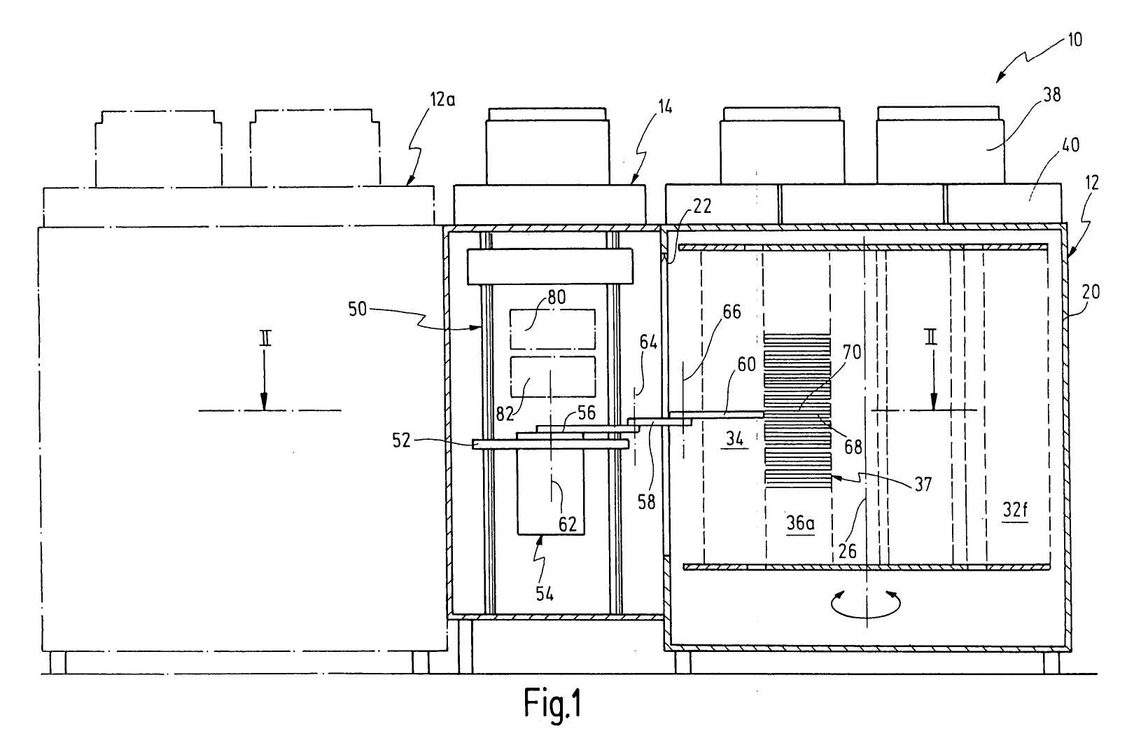

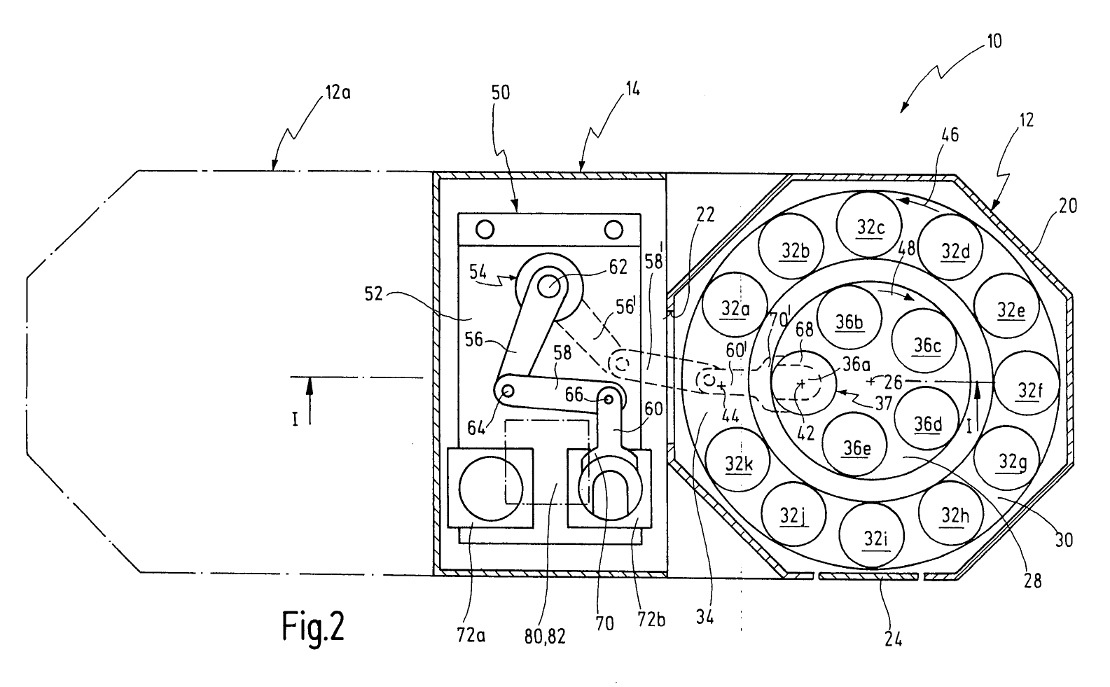

In FIGS. 1 and 2, a storage system for wafers is designated as a whole by 10. The concept of this storage system can also be applied to storage systems for reticles and other disk like objects used in the production of semiconductor products.

The storage system 10 has a storage module 12, which is laterally connected to an inserting and dispensing module 14. In exemplary embodiments of the invention there can even be two storage modules 12, 12a arranged on either side of the inserting and dispensing module 14, as indicated by dashed-dotted lines for a further storage module 12a. In addition, arrangements with three or more such storage modules are also conceivable.

The storage module 12 is provided with a closed housing 20, which merely has an opening 22 as an aperture at the transition to the inserting and dispensing module 14. Furthermore, a door 24 may be provided in the housing 20, in particular for servicing and repair purposes.

Inside the storage module 12 there is a carousel, which can rotate about a vertical axis 26. The carousel comprises an inner turntable 28 and an outer turntable 30. As can be clearly seen from FIG. 2, a total of eleven positions 32a to 32k and one empty position 34 are provided on the outer turntable 30. The inner turntable 28, on the other hand, has five positions 36a to 36e. In FIG. 1, a packet of wafers stacked one on top of the other is indicated by 37. Therefore, if a capacity of 175 wafers is assumed for each column-like packet 37, the storage module 12 with a total of 16 positions 32, 36 would have a total capacity of 2800 wafers.

Provided on the housing 20 are laminar flow units 38 and electrostatic discharge units 40. With these units it is possible to produce and ensure clean-room conditions inside the housing 20, the air located in the housing 20 also being from electrostatic charges as far as possible.

To transfer wafers into the storage module 12 or out of the storage module 12, two spatially fixed transfer positions are defined in the storage module 12, namely an inner transfer position 42 in the region of the inner turntable 28 and an outer transfer position 44 in the region of the outer turntable 30. The transfer positions 42, 44 are located on a common radial line, which intersects the vertical axis 26 and runs substantially centrally through the opening 22.

In FIG. 2, it is also indicated by arrows 46 and 48 that the inner turntable 28 and the outer turntable 30 can be driven independently of each other and also with different directions of rotation. Provided for this purpose are drives, which for the sake of clarity are not shown in the figure. This also applies to the associated control system, which is well known to a person skilled in the art.

Inside the inserting and dispensing module 14 there is a vertical unit 50 with carriages 52 running on vertical columns. The carriage 52 carries a robot 54. The robot 54 has a bending arm with a first arm part 56, a second arm part 58 and a third arm part 60. The robot 54 and the arm parts 56, 58, 60 are connected to one another via axes of rotation 62, 64 and 66. Here again, the drives and the control system of the robot 54 are not represented for the sake of clarity and because a person skilled in the art is familiar with such drives and control systems.

In FIG. 1 it is shown how the robot 54 removes a wafer 68 from the packet 37 with the arm parts 56, 58, 60. For this purpose, the third arm part 60 is provided at its free end with a hand 70. This operation is represented by dashed lines in FIG. 2.

In order to allow that the bending arm with the arm parts 56, 58, 60 can access the positions 36a to 36e of the inner turntable 28, it is required that the outer turntable 30 is first moved into a position in which the empty position 34 of the outer turntable 30 is on the outer transfer position 44.

In FIG. 2, it is shown by solid lines how the bending arm with the arm parts 56, 58, 60 transfers a wafer to the inserting and dispensing stations 72 on the right in FIG. 2.

Before this happens, an inspection or documentation of the wafers can be performed. Serving for this purpose is a code reader 80 and also what is called a “notch finder” 82. The notch finder 82 may be, for example, a digital camera.

These two last-mentioned units make use of the fact that wafers are usually provided with a semicircular indentation, the so-called “notch”, at a defined circumferential position. A marking, for example a bar code, is located on a surface of the wafer in a defined position in relation to the notch. This marking identifies the respective wafer and additionally indicates which processing stations it has already run through. Furthermore, the bar code serves the purpose of indicating the alignment of the crystallization of the wafer in relation to the notch.

Thus, if a wafer is removed from the storage module 12 for example, the robot 54 can first be made to move with the wafer in such a way that it is first detected in the notch finder 82 whether the notch is at the correct position. If this is the case, the wafer is moved further to the code reader 80. There, the marking is read out and the wafer is correspondingly documented.

If, on the other hand, the notch finder 82 establishes that the notch is not at the expected position, the robot 54 makes the wafer move to a turntable (not represented in the figure), on which the wafer is turned in such a way that the notch is then at the correct position. This can either be checked once again in the notch finder 82, or the wafer is then immediately passed on to the code reader 80.

As already mentioned several times, the storage system 10 according to the invention may either operate on the principle that the wafers are handled individually, or alternatively handling in baskets, i.e. with groups of wafers, is also possible. This of course also has an effect on the type of inserting and dispensing stations 72a, 72b on the inserting and dispensing module 14.

What is claimed is:

1. A storage system for storing a plurality of wafers, comprising
a storage module comprising at least one conveyor formed as a carousel and adapted to rotate about an axis of rotation, and
an inserting and dispensing module comprising a robot having a robot arm movable in a substantially horizontal plane, the inserting and dispensing module being located next to the storage module,
wherein the carousel has an inner turntable and an outer turntable capable of rotating independently of each other about the axis of rotation,
wherein the wafers are stored in a plurality of packets located on the inner turntable and the outer turntable, with the packets forming columns of wafers with one wafer above the other,
wherein the robot is configured to insert a specific wafer into one of the plurality of packets or to remove a specific wafer from one of the plurality of packets, and
wherein the conveyor is configured to bring the one of the plurality of packets into a transfer position at which the specific wafer can be transferred between the robot arm and the one packet.

2. The storage system of claim 1, wherein the axis of rotation is substantially vertical.

3. The storage system of claim 1, wherein the outer turntable has an empty location configured to allow the robot arm to pass through in order to transfer the specific wafer from the robot arm to the inner turntable and vice versa.

4. A system for storing objects used in the production of semiconductor products, the system comprising
at least one conveyor running substantially in a horizontal plane, and
a robot having a robot arm movable in the horizontal plane,
wherein the conveyor is configured to support a plurality of objects in column like arrangements with one object above the other,
wherein the robot is designed to insert a specific object into one of the column like arrangements or to remove the specific object from the one of the column like arrangements, and
wherein the conveyor is configured to bring the one of the column like arrangements into a transfer position at which the specific object can be transferred between the robot arm and the packet.

5. The system of claim 4, wherein the conveyor is formed as a carousel having an axis of rotation.

6. The system of claim 5, wherein the carousel has an inner turntable and an outer turntable capable of rotating independently of each other about the axis of rotation.

7. The system of claim 6, wherein the outer turntable has an empty location configured to allow the robot arm to pass through in order to transfer the specific object from the robot arm to the inner turntable and vice versa.

8. A storage system for storing objects comprising
at least one storage module for storing a plurality of objects, and
an inserting and dispensing module located next to the storage module,
wherein the storage module comprises at least one conveyor that runs substantially in a horizontal plane, and
wherein the inserting and dispensing module comprises a robot having a robot arm which is movable in the horizontal plane,
wherein the objects are stored in the storage module in a plurality of packets, with each packet being similar to a column with one object above the other, the packets being arranged on the at least one conveyor,
wherein the robot is configured to insert an object into one of the plurality of packets or to remove the object from the one of the plurality of packets, and
wherein the conveyor is configured to bring the one of the plurality of packets into a transfer position at which the object can be transferred between the robot arm and the packet.

9. The storage system of claim 8, wherein the conveyor is formed as a carousel having an axis of rotation.

10. The storage system of claim 9, wherein the carousel has an inner turntable and an outer turntable capable of rotating independently of each other about the axis of rotation.

11. The storage system of claim 10, wherein the outer turntable has an empty location configured to allow the robot arm to pass through in order to transfer the object from the robot arm to the inner turntable and vice versa.

12. The storage system of claim 8, comprising a plurality of baskets for transferring the object in groups.

13. The storage system of claim 8, comprising at least a first and a second storage module arranged next to the inserting and dispensing module, wherein the robot is in operative connection with both the first and the second storage module.

14. The storage system of claim 13, wherein the first and the second storage module are substantially identical.

15. The storage system of claim 8, further comprising a vertical unit for moving the robot in a vertical direction.

16. The storage system of claim 8, wherein the robot arm is a bending arm.

17. The storage system of claim 8, wherein the inserting and dispensing module further comprises a sensor and positioning unit for sensing and adjusting a rotational position of the object.

18. The storage system of claim 8, wherein the inserting and dispensing module comprises a reader for sensing and reading a marking on the object.

19. The storage system of claim 8, wherein the inserting and dispensing module comprises inserting and dispensing stations for transferring the object into and out of the storage system.

20. The storage system of claim 8, wherein the storage module comprises a housing having an opening facing the inserting and dispensing module, and comprises at least one from a laminar flow unit and an electrostatic discharge unit.

21. The storage system of claim 8, wherein the inserting and dispensing module comprises at least one from a laminar flow unit and an electrostatic discharge unit.
